(19) United States
(12) Patent Application Publication
(10) Pub. No.: US 2022/0084998 A1
(43) Pub. Date: Mar. 17, 2022

(54) DISPLAY DEVICE AND METHOD OF MANUFACTURING THE SAME

(71) Applicant: Samsung Display Co., LTD., Yongin-si (KR)

(72) Inventors: Hang Jae LEE, Yongin-si (KR); Sung Ho PARK, Yongin-si (KR); Sung Jae YUN, Yongin-si (KR); Jong Hyeok LEE, Yongin-s (KR); Jae Won CHOI, Yongin-si (KR)

(73) Assignee: Samsung Display Co., LTD., Yongin-si (KR)

(21) Appl. No.: 17/234,231

(22) Filed: Apr. 19, 2021

(30) Foreign Application Priority Data
Sep. 16, 2020 (KR) 10-2020-0119409

(51) Int. Cl. H01L 25/16; H01L 27/12

(52) U.S. Cl. CPC H01L 25/167; H01L 33/62; H01L 27/1288

(57) ABSTRACT

A display device includes a substrate including a plurality of pixels; a first bank disposed at a boundary of the plurality of pixels; a first electrode and a second electrode, spaced apart from each other on the substrate; an insulating layer disposed on the first electrode and the second electrode; and a plurality of light emitting elements disposed between the first electrode and the second electrode on the insulating layer. The first bank and the insulating layer are disposed on the same layer.

### CROSS-REFERENCE TO RELATED APPLICATION(S)

The application claims priority to and the benefit of Korean patent application 10-2020-0119409 under 35 U.S.C. § 119(a), filed on Sep. 16, 2020 in the Korean Intellectual Property Office (KIPO), the entire contents of which are incorporated herein by reference.

### BACKGROUND

### 1. Technical Field

The disclosure generally relates to a display device and a method of manufacturing the same.

### 2. Related Art

Recently, as interest in information displays is increased, research and development of display devices have been continuously conducted.

### SUMMARY

Embodiments provide a display device and a method of manufacturing the same, which can reduce manufacturing cost by decreasing a number of masks and simplifying a manufacturing process.

In accordance with an aspect of the disclosure, there is provided a display device including a substrate including a plurality of pixels; a first bank disposed at a boundary of the plurality of pixels; a first electrode and a second electrode spaced apart from each other on the substrate; an insulating layer disposed on the first electrode and the second electrode; and a plurality of light emitting elements disposed between the first electrode and the second electrode on the insulating layer, wherein the first bank and the insulating layer are disposed on a same layer.

The first bank and the insulating layer may include a same material.

The first bank and the insulating layer may include a chemically amplified resist (CAR).

The display device may further include a second bank disposed between the first and second electrodes and the substrate.

The first electrode and the second electrode may directly overlap the second bank.

The display device may further include a second bank disposed on the first electrode and the second electrode.

The second bank, the first bank, and the insulating layer may be disposed on a same layer.

The second bank, the first bank, and the insulating layer may include a same material.

The second bank may include a chemically amplified resist (CAR).

The display device may further include a first contact electrode electrically connecting an end of the light emitting element and the first electrode; and a second contact electrode electrically connecting another end of the light emitting element and the second electrode.

In accordance with another aspect of the disclosure, there is provided a method of manufacturing a display device, including providing a first electrode and a second electrode on a substrate on which a plurality of pixels are formed; providing a first bank at a boundary of the plurality of pixels; providing an insulating layer on the first electrode and the second electrode; and providing a plurality of light emitting elements between the first electrode and the second electrode on the insulating layer, wherein the first bank and the insulating layer are simultaneously formed.

The providing of the first bank and the insulating layer may include: providing an organic layer on the substrate; and simultaneously forming the first bank and the insulating layer by patterning the organic layer.

The organic layer may include a chemically amplified resist (CAR).

A mask may be used in the patterning of the organic layer, the mask including a first mask area corresponding to the first bank and a second mask area corresponding to the insulating layer. A transmittance of the first mask area may be different from a transmittance of the second mask area.

The method may further include providing a second bank between the first and second electrodes and the substrate.

The method may further include providing a second bank on the first electrode and the second electrode.

The second bank, the first bank, and the insulating layer may be simultaneously formed.

The providing of the second bank may include providing an organic layer on the substrate; and simultaneously forming the first bank, the second bank, and the insulating layer by patterning the organic layer.

The organic layer may include a chemically amplified resist (CAR).

The method may further include providing a first contact electrode electrically connecting one end of the light emitting element and the first electrode, and a second contact electrode electrically connecting another end of the light emitting element and the second electrode.

### BRIEF DESCRIPTION OF THE DRAWINGS

Some embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIGS. 1 and 2 are a schematic perspective view and a cross-sectional view illustrating a light emitting element in accordance with an embodiment of the disclosure.

FIG. 3 is a schematic plan view illustrating a display device in accordance with an embodiment of the disclosure.

FIGS. 4 to 6 are schematic circuit diagrams each illustrating a pixel in accordance with an embodiment of the disclosure.

FIGS. 7 and 8 are schematic cross-sectional views each illustrating a pixel in accordance with an embodiment of the disclosure.

FIG. 9 is a schematic cross-sectional view illustrating a pixel of a display device in accordance with another embodiment of the disclosure.

FIGS. 10 to 14 are schematic cross-section views illustrating a method of manufacturing a display device in accordance with an embodiment of the disclosure.

FIGS. 15 to 18 are schematic cross-section views illustrating a method of manufacturing a display device in accordance with another embodiment of the disclosure.

### DETAILED DESCRIPTION OF THE EMBODIMENTS

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms. The embodiments are provided by way of example only so that a person of ordinary skilled in the art can more fully understand the features in the disclosure and the scope thereof.

The terminology used herein is for the purpose of describing particular embodiments only and is not construed as limiting the disclosure. As used herein, the singular forms are intended to include the plural forms as well, unless the context clearly indicates otherwise. The terms “comprises/includes” and/or “comprising/including,” when used in this specification, specify the presence of mentioned component, step, operation and/or element, but do not exclude the presence or addition of one or more other components, steps, operations and/or elements.

When described as that any element is “connected,” “coupled,” or “accessed” to another element, it should be understood that it is possible that still another element may “connected,” “coupled,” or “accessed” between the two elements as well as that the two elements are directly “connected,” “coupled,” or “accessed” to each other.

The term “on” that is used to designate that an element or layer is on another element or layer includes a case where an element or layer is located directly on another element or layer, and a case where an element or layer is located on another element or layer via still another element layer. Like reference numerals generally denote like elements throughout the specification.

It will be understood that, although the terms “first,” “second,” and the like may be used herein to describe various elements, these elements should not be limited by these terms. These terms are only used to distinguish one element from another element. Thus, a “first” element discussed below could also be termed a “second” element without departing from the teachings of the disclosure.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in more detail with reference to the accompanying drawings.

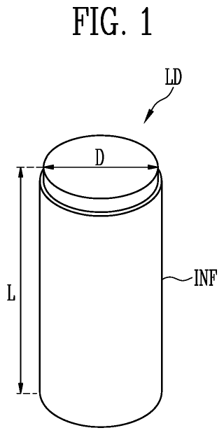

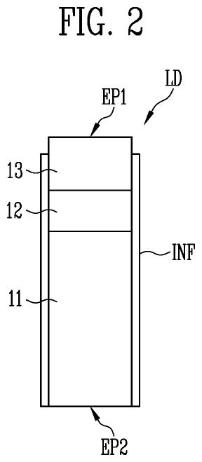

FIGS. 1 and 2 are schematic perspective and cross-sectional views illustrating a light emitting element (or light emitting diode) in accordance with an embodiment. Although a pillar-shaped light emitting element LD is illustrated in FIGS. 1 and 2, the kind and/or shape of the light emitting element LD is not limited thereto.

Referring to FIGS. 1 and 2, the light emitting element LD may include a first semiconductor layer 11, a second semiconductor layer 13, and an active layer 12 interposed between the first and second semiconductor layers 11 and 13. In an example, in case that assuming that an extending direction of the light emitting element LD is a longitudinal direction (L), the light emitting element LD may include the first semiconductor layer 11, the active layer 12, and the second semiconductor layer 13, which are sequentially stacked each other in the longitudinal direction (L).

The light emitting element LD may be provided in a pillar shape extending in a direction. The light emitting element LD may have a first end portion EP1 and a second end portion EP2. One of the first and second semiconductor layers 11 and 13 may be disposed at the first end portion EP1 of the light emitting element LD. The other of the first and second semiconductor layers 11 and 13 may be disposed at the second end portion EP2 of the light emitting element LD.

In some embodiments, the light emitting element LD may be a light emitting element manufactured in a pillar shape by an etching process, etc. In the specification, the term “pillar shape” may include a rod-like shape or bar-like shape, which is long in the longitudinal direction (L) (for example, its aspect ratio is greater than 1) such as a cylinder or a polyprism and the shape of its section is not particularly limited. For example, a length L of the light emitting element LD may be greater than a diameter D (or a width of a cross-section) of the light emitting element LD.

The light emitting element LD may have a size small to a degree of nanometer scale to micrometer scale. In an example, the light emitting element LD may have a diameter D (or width) in a range of nanometer scale to micrometer scale and/or a length L in a range of nanometer scale to micrometer scale. However, the size of the light emitting element LD is not limited thereto, and the size of the light emitting element LD may be variously changed according to design conditions of various types of devices, e.g., a display device, and the like, which use, as a light source, a light emitting apparatus using the light emitting element LD.

The first semiconductor layer 11 may be a first conductivity type (or conductive) semiconductor layer. For example, the first semiconductor layer 11 may include an N-type semiconductor layer. In an example, the first semiconductor layer 11 may include one semiconductor material of InAlGaN, GaN, AlGaN, InGaN, AlN, and InN, and include an N-type semiconductor layer doped with a first conductivity type dopant such as Si, Ge or Sn. However, the material constituting the first semiconductor layer 11 is not limited thereto. The first semiconductor layer 11 may be configured with (or formed of) various materials.

The active layer 12 may be formed on the first semiconductor layer 11 and may be formed in a single-quantum well structure or a multi-quantum well (MQW) structure. The position of the active layer 12 may be variously changed according to a kind of the light emitting element LD.

A clad layer (not shown) doped with a conductive dopant may be formed on the top and/or the bottom of the active layer 12. In an example, the clad layer may be formed as an AlGaN layer or InAlGaN layer. In some embodiments, a material such as AlGaN or AlInGaN may be used to form the active layer 12. The active layer 12 may be formed of various materials.

The second semiconductor layer 13 may be formed on the active layer 12 and may include a semiconductor layer having a type different from that of the first semiconductor layer 11. For example, the second semiconductor layer 13 may include a P-type semiconductor layer. In an example, the second semiconductor layer 13 may include at least one semiconductor material of InAlGaN, GaN, AlGaN, InGaN, AlN, and InN, and include a P-type semiconductor layer doped with a second conductivity type dopant such as Mg. However, the material forming (or constituting) the second semiconductor layer 13 is not limited thereto. The second semiconductor layer 13 may be formed of various materials.

In case that a voltage greater than or equal to a threshold voltage is applied to both ends of the light emitting element LD, the light emitting element LD may emit light as electron-hole pairs are combined in the active layer 12. The light emission of the light emitting element LD may be controlled by using such a principle, so that the light emitting element LD may be used as a light source for various light emitting apparatuses such as a pixel of a display device.

The light emitting element LD may further include an insulative film INF provided on a surface thereof. The insulative film INF may be formed on the surface of the light emitting element LD to at least surround the outer circumference of the active layer 12. The insulative film INF may further surround an area of each of the first and second semiconductor layers 11 and 13.

In some embodiments, the insulative film INF may expose both end portions of the light emitting element LD. For example, the insulative film INF may expose an end of each of the first and second semiconductor layers 11 and 13 located at the first and second end portions EP1 and EP2 of the light emitting element LD. In another embodiment, the insulative film INF may expose a side portion of each of the first and second semiconductor layers 11 and 13 adjacent to the first and second end portions EP1 and EP2 of the light emitting element LD, which have different polarities.

In some embodiments, the insulative film INF may include at least one insulating material of silicon oxide (SiOₓ), silicon nitride (SiNₓ), silicon oxynitride (SiOₓN_{y}), aluminum oxide (AlₓO_{y}), and titanium dioxide (TiOₓ) and may be configured (or formed) as a single layer or a multi-layer (e.g., a double layer configured with aluminum oxide (AlₓO_{y}) and silicon oxide (SiOₓ). However, the disclosure is not limited thereto. In some embodiments, the insulative film INF may be omitted.

In case that the insulative film INF is provided to cover or overlap the surface of the light emitting element LD, particularly, an outer circumferential surface of the active layer 12, the insulative film INF may prevent the active layer 12 from being short-circuited with a first pixel electrode, a second pixel electrode, or the like, which will be described below. Accordingly, the electrical stability of the light emitting element LD may be ensured.

In case that the insulative film INF is provided on the surface of the light emitting element LD, a surface defect in the light emitting element LD may be reduced or minimized, and thus the lifespan and efficiency of the light emitting element LD may be improved. Even in case that the light emitting elements LD are disposed adjacent to each other, an unwanted short circuit may be prevented from occurring between the light emitting elements LD.

In an embodiment, the light emitting element LD may further include an additional component, in addition to the first semiconductor layer 11, the active layer 12, the second semiconductor 13, and/or the insulative film INF surrounding the same. For example, the light emitting element LD may additionally include at least one phosphor layer, at least one active layer, at least one semiconductor layer, and/or at least one electrode layer, which are disposed at first ends of the first semiconductor layer 11, the active layer 12, and/or the second semiconductor layer 13. In an example, a contact electrode layer may be disposed at each of the first and second end portions EP1 and EP2 of the light emitting element LD. Although the pillar-shaped light emitting element LD has been exemplified in FIGS. 1 and 2, the kind, structure, and/or shape of the light emitting element LD may be variously changed. For example, the light emitting element LD may be formed in a core-shell structure having a polypyramid shape.

A light emitting apparatus including the above-described light emitting element LD may be used in various kinds of devices which require a light source, including a display device. For example, light emitting elements LD may be disposed in each pixel of a display panel and be used as a light source of each pixel. However, the application field of the light emitting element LD is not limited to the above-described example. For example, the light emitting element LD may be used in other types of devices that require a light source such as a lighting device.

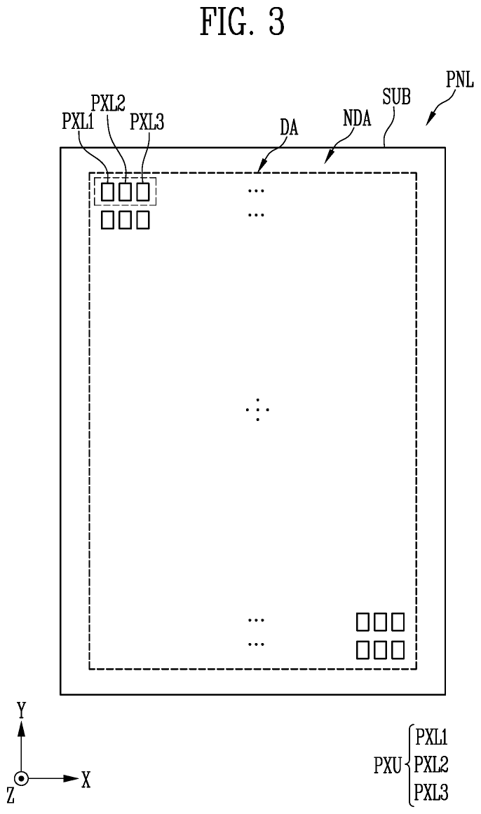

FIG. 3 is a schematic plan view illustrating a display device in accordance with an embodiment with respect to first, second, and third directions (or X-axis direction, Y-axis direction, and Z-axis direction).

In FIG. 3, a display device, particularly, a display panel PNL provided in the display device will be illustrated as an example of an electronic device which may use, as a light source, the light emitting element LD described in the embodiment(s) illustrated in FIGS. 1 and 2.

Each pixel unit PXU of the display panel PNL and each pixel forming the pixel unit PXU may include at least one light emitting element LD. For the sake of convenience, in FIG. 3, a structure of the display panel PNL will be briefly illustrated based on a display area DA. However, in some embodiments, at least one driving circuit (e.g., at least one of a scan driver and a data driver), lines, and/or pads, which are not shown in the drawing, may be further disposed in the display panel PNL.

Referring to FIG. 3, the display panel PNL may include a substrate SUB and a pixel unit PXU disposed on the substrate SUB. The pixel unit PXU may include first pixels PXL1, second pixels PXL2, and/or third pixels PXL3. Hereinafter, in case that at least one pixel of the first pixels PXL1, the second pixels PXL2, and the third pixels PXL3 is arbitrarily denoted or in case that two or more kinds of pixels of the first pixels PXL1, the second pixels PXL2, and the third pixels PXL3 are inclusively denoted, the at least one pixel or the two or more kinds of pixels will be referred to as a “pixel PXL” or “pixels PXL.”

The substrate SUB may form a base member of the display panel PNL and may be a rigid or flexible substrate or film. In an example, the substrate SUB may be a rigid substrate made of glass or tempered glass, a flexible substrate (or thin film) made of a plastic or metal material, or an insulating layer including at least one layer. The material and/or property of the substrate SUB is not particularly limited.

In an embodiment, the substrate SUB may be substantially transparent. The term “substantially transparent” may mean that light may be transmitted with a predetermined transmittance or more. In another embodiment, the substrate SUB may be translucent or opaque. The substrate SUB may include a reflective material in some embodiments.

The display panel PNL and the substrate SUB for forming the same may include a display area DA for displaying an image and a non-display area NDA except the display area DA.

Pixels PXL may be arranged in the display area DA. Various lines, pads, and/or a built-in circuit, which are electrically connected to the pixels PXL of the display area DA, may be disposed in the non-display are NDA. The pixels PXL may be regularly arranged in the display area DA according to a stripe structure, a PenTile® structure, or the like. However, the arrangement structure of the pixels PXL is not limited thereto, and the pixels PXL may be arranged in the display area DA by using various structures and/or methods.

In some embodiments, two or more kinds of pixels PXL emitting lights of different colors may be disposed in the display area DA. In an example, first pixels PXL1 emitting light of a first color, second pixels PXL2 emitting light of a second color, and third pixels PXL3 emitting light of a third color may be arranged in the display area DA. At least one first pixel PXL1, a least one second pixel PXL2, and at least one third pixel PXL3, which are disposed adjacent to each other, may form a pixel unit PXU capable of emitting light of various colors. For example, each of the first to third pixels PXL1, PXL2, and PXL3 may be a sub-pixel emitting light of a predetermined color. In some embodiments, the first pixel PXL1 may be a red pixel emitting light of red, the second pixel PXL2 may be a green pixel emitting light of green, and the third pixel PXL3 may be a blue pixel emitting light of blue. However, the disclosure is not limited thereto.

In an embodiment, the first pixel PXL1, the second pixel PXL2, and the third pixel PXL3 may respectively include, as light sources, a light emitting element of the first color, a light emitting element of the second color, and a light emitting element of the third color, so that the light emitting elements LD may emit light of the first color, the second color, and the third color, respectively. In another embodiment, the first pixel PXL1, the second pixel PXL2, and the third pixel PXL3 may include light emitting elements emitting light of the same color and may include color conversion layers and/or color filters of different colors, which are disposed on the respective light emitting elements, to emit light of the first color, the second color, and the third color, respectively. However, the color, kind, and/or number of pixels PXL forming each pixel unit PXU are not particularly limited. In an example, the color of light emitted by each pixel PXL may be variously changed.

The pixel PXL may include at least one light source driven by a predetermined control signal (e.g., a scan signal and a data signal) and/or a predetermined power source (e.g., a first power source and a second power source). In an embodiment, the light source may include at least one light emitting element LD in accordance with the embodiment shown in FIGS. 1 and 2, e.g., a subminiature pillar-shaped light emitting element LD having a small size to a degree of nanometer scale to micrometer scale. However, the disclosure is not necessarily limited thereto. Various types of light emitting elements LD may be used as the light source of the pixel PXL.

In an embodiment, each pixel PXL may be formed as an active pixel. However, the kind, structure, and/or driving method of pixels PXL which may be applied to the display device are not particularly limited. For example, each pixel PXL may be configured as (or formed as) a pixel of a passive or active light emitting display device using various structures and/or driving methods.

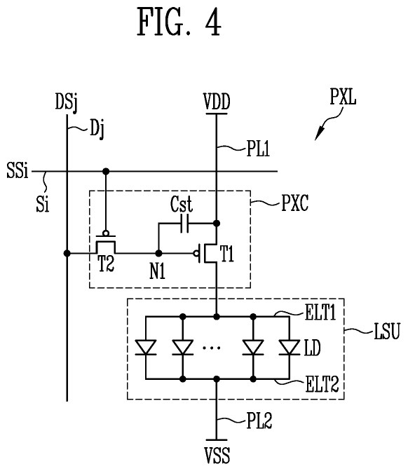

FIGS. 4 to 6 are schematic circuit diagrams each illustrating a pixel in accordance with an embodiment. For example, FIGS. 4 to 6 illustrate embodiments of a pixel PXL applicable to an active display device. However, the kinds of the pixel PXL and the display device are not limited thereto.

In some embodiments, each of the pixels PXL illustrated in FIGS. 4 to 6 may be one of the first pixel PXL1, the second pixel PXL2, and the third pixel PXL3, provided in the display panel PNL illustrated in FIG. 3. The first pixel PXL1, the second pixel PXL2, and the third pixel PXL3 may substantially have the same structure or similar structures.

Referring to FIG. 4, the pixel PXL may include a light source unit LSU for generating light with a luminance corresponding to a data signal and a pixel circuit PXC for driving the light source unit LSU.

The light source unit LSU may include at least one light emitting element LD electrically connected between a first power source VDD and a second power source VSS. For example, the light source unit LSU may include a first electrode ELT1 (also referred to as a “first pixel electrode” or “first alignment electrode”) electrically connected to the first power source VDD via the pixel circuit PXC and a first power line PL1, a second electrode ELT2 (also referred to as a “second pixel electrode” or “second alignment electrode”) electrically connected to the second power source VSS through a second power line PL2, and light emitting elements LD electrically connected in the same direction between the first and second electrodes ELT1 and ELT2. In an embodiment, the first electrode ELT1 may be an anode electrode, and the second electrode ELT2 may be a cathode electrode.

Each of the light emitting elements LD may include a first end portion (e.g., a P-type end portion) electrically connected to the first power source VDD through the first electrode ELT1 and/or the pixel circuit PXC and a second end portion (e.g., an N-type portion) electrically connected to the second power source VSS through the second electrode ELT2. For example, the light emitting elements LD may be electrically connected in parallel in a forward direction between the first and second electrodes ELT1 and ELT2. Each of the light emitting elements LD electrically connected in the forward direction between the first power source VDD and the second power source VSS may form an effective light source, and the effective light sources may form the light source unit LSU of the pixel PXL.

The first power source VDD and the second power source VSS may have different potentials such that the light emitting elements LD may emit light. In an example, the first power source VDD may be set as a high-potential power source, and the second power source VSS may be set as a low-potential power source. A potential difference between the first power source VDD and the second power source VSS may be set to a voltage equal to or greater than a threshold voltage of the light emitting elements LD during at least an emission period of the pixel PXL.

First end portions (e.g., P-type end portions) of the light emitting elements LD forming each light source unit LSU may be commonly connected to the pixel circuit PXC through an electrode (e.g., the first electrode ELT1 of each pixel PXL) of the light source unit LSU and may be electrically connected to the first power source VDD through the pixel circuit PXC and the first power line PL1. The other end portions (e.g., N-type end portions) of the light emitting elements LD may be commonly connected to the second power source VSS through another electrode (e.g., the second electrode ELT2 of each pixel PX) and the second power line PL2.

The light emitting elements LD may emit light with a luminance corresponding to a driving current supplied through a corresponding pixel circuit PXC. For example, during each frame period, the pixel circuit PXC may supply, to the light source unit LSU, a driving current corresponding to a grayscale value to be expressed in a corresponding frame. The driving current supplied to the light source unit LSU may be divided to flow through the light emitting elements LD electrically connected in the forward direction. Accordingly, each light emitting device LD may emit light with a luminance corresponding to a current flowing therethrough, so that the light source unit LSU may emit light with a luminance corresponding to the driving current.

The pixel circuit PXC may be electrically connected between the first power source VDD and the first electrode ELT1. The pixel circuit PXC may be electrically connected to a scan line Si and a data line Dj of a corresponding pixel PXL. In an example, in case that assuming that the pixel PXL is disposed on an i-th (where i is a natural number) horizontal line (row) and a j-th (where j is a natural number) vertical line (column) of the display area DA, the pixel circuit PXC of the pixel PXL may be electrically connected to an i-th scan line Si and a j-th data line Dj of the display area DA.

In some embodiments, the pixel circuit PXC may include transistors and at least one capacitor. For example, the pixel circuit PXC may include a first transistor T1, a second transistor T2, and a storage capacitor Cst.

The first transistor T1 may be electrically connected between the first power source VDD and the light source unit LSU. For example, a first electrode (e.g., a source electrode) of the first transistor T1 may be electrically connected to the first power source VDD, and a second electrode (e.g., a drain electrode) of the first transistor T1 may be electrically connected to the first electrode ELT1. A gate electrode of the first transistor T1 may be electrically connected to a first node N1. The first transistor T1 may control a driving current supplied to the light source unit LSU, corresponding to a voltage of the first node N1. For example, the first transistor T1 may be a driving transistor which controls a driving current of the pixel PXL.

The second transistor T2 may be electrically connected between the data line Dj and the first node N1. For example, a first electrode (e.g., a source electrode) of the second transistor T2 may be electrically connected to the data line Dj, and a second electrode (e.g., a drain electrode) of the second transistor T2 may be electrically connected to the first node N1. A gate electrode of the second transistor T2 may be electrically connected to the scan line Si. In case that a scan signal SSi having a gate-on voltage (e.g., low-level voltage) is supplied from the scan line Si, the second transistor T2 may be turned on to electrically connect the data line Dj and the first node N1.

A data signal DSj of a corresponding frame may be supplied to the data line Dj in each frame period. The data signal DSj may be transferred to the first node N1 through the second transistor T2 turned on during a period in which the scan signal SSi having the gate-on voltage is supplied to the second transistor T2. For example, the second transistor T2 may be a switching transistor for transferring each data signal DSj to the inside of the pixel PXL.

An electrode of the storage capacitor Cst may be electrically connected to the first power voltage VDD, and the other electrode of the storage capacitor Cst may be electrically connected to the first node N1. The storage capacitor Cst may store a voltage corresponding to the data signal DSj supplied to the first node N1 during each frame period.

Although the transistors, e.g., the first and second transistors T1 and T2 included in the pixel circuit PXC are illustrated as P-type transistors in FIG. 4, the disclosure is not limited thereto. For example, at least one of the first and second transistors T1 and T2 may be changed to an N-type transistor. The pixel circuit PXC may be configured as a pixel circuit having various structures and/or may be driven by various driving methods.

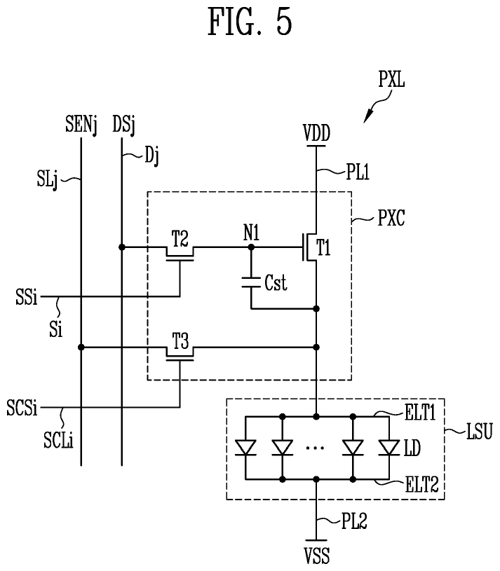

Referring to FIG. 5, the pixel circuit PXC may be further electrically connected to a sensing control line SCLi and a sensing line SLj. In an example, the pixel circuit PXC of the pixel PXL disposed on the i-th horizontal line and the j-th vertical line of the display area DA may be electrically connected to an i-th sensing control line SCLi and a j-th sensing line SLj of the display area DA. The pixel circuit PXC may further include a third transistor T3. As another example, in another embodiment, the sensing line SLj may be omitted, and a characteristic of a corresponding pixel PXL (or adjacent pixel) may be detected by detecting a sensing signal SENj through a data line Dj of the pixel PXL.

The third transistor T3 may be electrically connected between the first transistor T1 and the sensing line SLj. For example, an electrode of the third transistor T3 may be electrically connected to an electrode (e.g., a source electrode) of the first transistor T1 connected to the first electrode ELT1, and another electrode of the third transistor T3 may be electrically connected to the sensing line SLj. In case that the sensing line SLj is omitted, the another electrode of the third transistor T3 may be electrically connected to the data line Dj.

A gate electrode of the third transistor T3 may be electrically connected to the sensing control line SCLi. In case that the sensing control line SCLi is omitted, the gate electrode of the third transistor T3 may be electrically connected to the scan line Si. The third transistor T3 may be turned on by a sensing control signal SCSI having a gate-on voltage (e.g., a high level voltage), which is supplied to the sensing control line SCLi during a predetermined sensing period, to electrically connect the sensing line SLj and the first transistor T1.

In some embodiments, the sensing period may be a period in which a characteristic (e.g., a threshold voltage of the first transistor T1, etc.) of each of the pixels PXL disposed in the display area DA is extracted or sensed. During the sensing period, the first transistor T1 may be turned on by supplying, to the first node N1, a predetermined reference voltage at which the first transistor T1 may be turned on, through the data line Dj and the second transistor T2, or by electrically connecting each pixel PXL to a current source, etc. The first transistor T1 may be electrically connected to the sensing line SLj in case that the third transistor T3 is turned on by supplying the sensing control signal SCSI having the gate-on voltage to the third transistor T3. Subsequently, the sensing signal SENj may be acquired through the sensing line SLj, and a characteristic of each pixel PXL, including the threshold voltage of the first transistor T1, etc., may be detected by using the sensing signal SENj. Information on the characteristic of each pixel PXL may be used to convert image data such that a characteristic deviation between the pixels PXL disposed in the display area DA may be compensated for.

Although an embodiment in which the first, second, and third transistors T1, T2, and T3 are all N-type transistors has been illustrated in FIG. 5, the disclosure is not limited thereto. For example, at least one of the first, second, and third transistors T1, T2, and T3 may be changed to a P-type transistor.

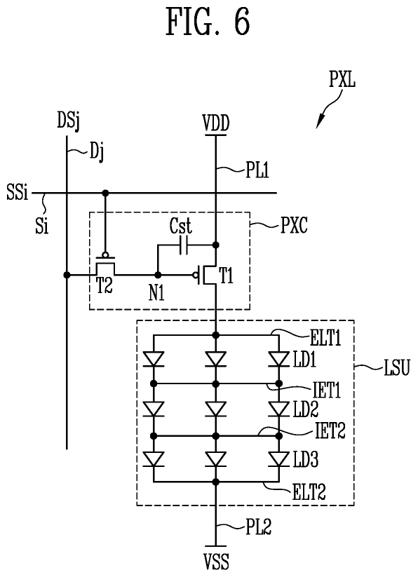

Although an embodiment in which effective light sources, for example, light emitting elements LD forming each light source unit LSU are electrically connected in parallel has been illustrated in FIGS. 4 and 5, the disclosure is not necessarily limited thereto. For example, the light source unit LSU of each pixel PXL may be configured to include a serial structure having at least two stages as illustrated in FIG. 6. In the embodiment illustrated in FIG. 6, detailed descriptions of components (e.g., a pixel circuit PXC) similar or identical to those of the embodiments illustrated in FIGS. 4 and 5 will be omitted.

Referring to FIG. 6, the light source unit LSU may include at least two light emitting elements electrically connected in series to each other. In an example, the light source unit LSU may include a first light emitting element LD1, a second light emitting element LD2, and a third light emitting element LD3, which are electrically connected in series in a forward direction between the first power source VDD and the second power source VSS. Each of the first, second, and third light emitting elements LD1, LD2, and LD3 may form an effective light source.

Hereinafter, in case that a specific light emitting element of the first, second, and third light emitting elements LD1, LD2, and LD3 is denoted, the corresponding light emitting element will be referred to as a “first light emitting element LD1,” a “second light emitting element LD2,” or a “third light emitting element LD3.” In case that at least one light emitting element of the first, second, and third light emitting elements LD1, LD2, and LD3 is arbitrarily denoted or the first, second, and third light emitting elements LD1, LD2, and LD3 are inclusively denoted, the corresponding light emitting element or the corresponding light emitting elements will be referred to as a “light emitting element LD” or “light emitting elements LD.”

A first end portion (e.g., a P-type end portion) of the first light emitting element LD1 may be electrically connected to the first power source VDD via a first electrode (i.e., a first pixel electrode) ELT1 of the light source unit LSU, etc. A second end portion (e.g., an N-type end portion) of the first light emitting element LD1 may be electrically connected to a first end portion (e.g., a P-type end portion) of the second light emitting element LD2 through a first intermediate electrode IET1.

The first end portion of the second light emitting element LD2 may be electrically connected to the second end portion of the first light emitting element LD1. A second end portion (e.g., an N-type end portion) of the second light emitting element LD2 may be electrically connected to a first end portion (e.g., a P-type end portion) of the third light emitting element LD3 through a second intermediate electrode IET2.

The first end portion of the third light emitting element LD3 may be electrically connected to the second end portion of the second light emitting element LD2. A second end portion (e.g., an N-type end portion) of the third light emitting element LD3 may be electrically connected to the second power source VSS via a second electrode (i.e., a second pixel electrode) ELT2 of the light source unit LSU. In the above-described manner, the first, second, and third light emitting elements LD1, LD2, and LD3 may be sequentially electrically connected in series between the first and second electrodes ELT1 and ELT2 of the light source unit LSU.

Although an embodiment in which the light emitting elements LD are electrically connected in a three-stage serial structure has been illustrated in FIG. 6, the disclosure is not limited thereto. For example, in an embodiment, two light emitting elements LD may be electrically connected in a two-stage serial structure, or four or more light emitting elements LD may be electrically connected in a serial structure having four or more stages.

When assuming that the same luminance is expressed (or displayed) using light emitting elements LD under the same condition (e.g., the same size and/or the same number), in a light source unit LSU having a structure in which the light emitting elements LD are electrically connected in series a voltage applied between first and second electrodes ELT1 and ELT2 may increase and the magnitude of a driving current flowing through the light source unit LSU may decrease, as compared with a light source unit LSU having a structure in which the light emitting elements LD are electrically connected in parallel. Therefore, in case that the light source unit LSU of each pixel PXL is configured to have the serial structure, a panel current flowing through the display panel PNL may be reduced.

Similar to the above-described embodiments, each light source unit LSU may include light emitting elements LD electrically connected in the forward direction between the first and second power sources VDD and VSS to form respective effective light sources. In some embodiments, a connection structure between the light emitting elements LD may be variously modified. For example, the light emitting elements LD may be electrically connected only in series or parallel to each other or may be electrically connected in a serial/parallel hybrid structure.

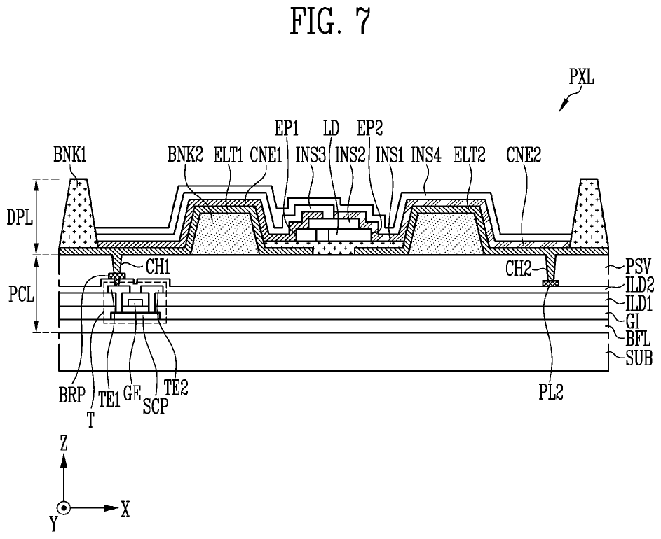

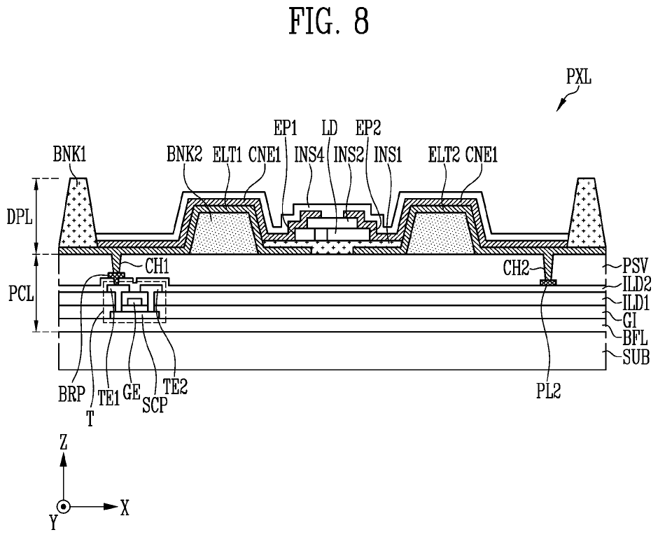

FIGS. 7 and 8 are schematic sectional views each illustrating a pixel in accordance with an embodiment.

In each of FIGS. 7 and 8, a structure of each pixel PXL will be schematically illustrated based on a light emitting element LD, and a transistor T electrically connected to a first electrode ELT1 will be illustrated among various circuit elements forming a pixel circuit PXC. Hereinafter, in case that a first transistor T1 is designated without being distinguished from other transistors, the first transistor T1 will be inclusively referred to as a “transistor T.”

Structures and/or positions for each layer of transistors T are not limited to the embodiments illustrated in FIGS. 7 and 8 and may be variously changed in some embodiments. In an embodiment, transistors T forming each pixel circuit PXC may substantially have the same structure or similar structures, but the disclosure is not limited thereto. For example, in another embodiment, at least one of the transistors T forming the pixel circuit PXC may have a sectional structure different from that of the other transistors T, and/or may be disposed in or on a layer different from that of the other transistors T.

Referring to FIGS. 7 and 8, the pixel PXL and the display device having the same may include a substrate SUB and a circuit layer PCL and a display layer DPL, which are disposed on a surface of the substrate SUB. In some embodiments, a color conversion layer and/or color filter layer may be further disposed on the display layer DPL, but the disclosure is not limited thereto.

The circuit layer PCL may include circuit elements forming a pixel circuit PXC of each pixel PXL and various lines electrically connected thereto. The display layer DPL may include electrodes (e.g., first and second electrodes ELT1 and ELT2 and/or first and second contact electrodes CNE1 and CNE2) and light emitting elements LD, which form a light source unit LSU of each pixel PXL.

The circuit layer PCL may include at least one circuit element electrically connected to light emitting elements LD of each pixel PXL. For example, the circuit layer PCL may include transistors T disposed in each pixel area to form a pixel circuit PXC of a corresponding pixel PXL. The circuit layer PCL may further include at least one power line and/or at least one signal line electrically connected to each pixel circuit PXC and/or each light source unit LSU. For example, the circuit layer PCL may include a first power line PL1, a second power line PL2, and a scan line Si and a data line Dj of each pixel PXL.

The circuit layer PCL may include insulating layers. For example, the circuit layer PCL may include a buffer layer BFL, a gate insulating layer GI, a first interlayer insulating layer ILD1, a second interlayer insulating layer ILD2, and/or a passivation layer PSV, which are sequentially stacked on the surface of the substrate SUB. The circuit layer PCL may selectively further include at least one light blocking pattern (not shown) or the like, which is disposed on the bottom of at least some transistors T.

The buffer layer BFL may prevent an impurity from being diffused into each circuit element. The buffer layer BFL may be formed as a single layer but may be configured as a multi-layer including at least two layers. In case that the buffer layer BFL is provided as a multi-layer, the layers may be formed of the same material or different materials. Various circuit elements such as transistors T and various lines electrically connected to the circuit elements may be disposed on the buffer layer BFL. In some embodiments, the buffer layer BFL may be omitted.

Each transistor T may include a semiconductor pattern SCP (also referred to as a “semiconductor layer” or “active layer”), a gate electrode GE, and first and second transistor electrodes TE1 and TE2. Although an embodiment in which each transistor T includes the first and second transistor electrodes TE1 and TE2 formed separately from the semiconductor pattern SCP is illustrated in FIGS. 7 and 8, the disclosure is not limited thereto. For example, in another embodiment, the first transistor electrode TE1 and/or the second transistor electrode TE2, provided in at least transistor T, may be integral with each semiconductor pattern SCP.

The semiconductor pattern SCP may be disposed on the buffer layer BFL. In an example, the semiconductor pattern SCP may be disposed between the substrate SUB on which the buffer layer BFL is formed and the gate insulating layer GI. The semiconductor pattern SCP may include a first region contacting each first transistor electrode TE1, a second region contacting each second transistor electrode ET2, and a channel region located between the first and second regions. In some embodiments, one of the first and second regions may be a source region, and the other of the first and second regions may be a drain region.

In some embodiments, the semiconductor pattern SCP may be a semiconductor pattern made of poly-silicon, amorphous silicon, oxide semiconductor, etc. The channel region of the semiconductor pattern SCP may be a semiconductor pattern not doped with an impurity and may be an intrinsic semiconductor. Each of the first and second regions of the semiconductor pattern SCP may be a semiconductor pattern doped with a predetermined impurity.

In an embodiment, semiconductor patterns SCP of transistors T forming each pixel circuit PXC may be made of (or include) substantially the same material or similar materials. For example, the semiconductor patterns SCP of the transistors T may be made of the same material, e.g., one of polysilicon, amorphous silicon, and an oxide semiconductor.

In another embodiment, some and the others of the transistors T may include semiconductor patterns SCP made of different materials. For example, the semiconductor patterns SCP of some transistors among the transistors T may be made of polysilicon or amorphous silicon, and the semiconductor patterns SCP of the other transistors among the transistors T may be made of an oxide semiconductor.

The gate insulating layer GI may be disposed over or on the semiconductor pattern SCP. In an example, the gate insulating layer GI may be disposed between the semiconductor pattern SCP and the gate electrode GE. The gate insulating layer GI may be configured or formed as a single layer or a multi-layer and may include various kinds of organic/inorganic insulating materials including silicon nitride (SiNₓ), silicon oxide (SiOₓ), silicon oxynitride (SiOₓN_{y}), or the like.

The gate electrode GE may be disposed on the gate insulating layer GI. For example, the gate electrode GE may be disposed to overlap the semiconductor pattern SCP with the gate insulating layer GI interposed therebetween. The transistor T having a top-gate structure is illustrated in FIGS. 7 and 8. In another embodiment, the transistor T may have a bottom-gate structure. The gate electrode GE may be disposed on the bottom of the semiconductor pattern SCP to overlap the semiconductor pattern SCP.

The first interlayer insulating layer ILD1 may be disposed over the gate electrode GE. In an example, the first interlayer insulating layer ILD1 may be disposed between the gate electrode GE and the first and second transistor electrodes TE1 and TE2. The first interlayer insulating layer ILD1 may be formed as a single layer or a multi-layer and may include at least one inorganic insulating material and/or at least one organic insulating material. For example, the first interlayer insulating layer ILD1 may include various kinds of organic/inorganic insulating materials including silicon nitride (SiNₓ), silicon oxide (SiOₓ), silicon oxynitride (SiOₓN_{y}), or the like. However, the material forming the first interlayer insulating layer ILD1 is not particularly limited.

The first and second transistor electrodes TE1 and TE2 may be disposed on each semiconductor pattern SCP with at least one first interlayer insulating layer ILD1 interposed therebetween. For example, the first and second transistor electrodes TE1 and TE2 may be disposed on different end portions of the semiconductor pattern SCP with the gate insulating layer GI and the first interlayer insulating layer ILD1, which are interposed therebetween. The first and second transistor electrodes TE1 and TE2 may be electrically connected to each semiconductor pattern SCP. For example, the first and second transistor electrodes TE1 and TE2 may be respectively electrically connected to the first and second regions of the semiconductor pattern SCP through contact holes penetrating through the gate insulating layer GI and the first interlayer insulating layer ILD1. In some embodiments, one of the first and second transistor electrodes TE1 and TE2 may be a source electrode, and the other may be a drain electrode.

At least one transistor T provided in the pixel circuit PXC may be electrically connected to at least one pixel electrode. In an example, the transistor T may be electrically connected to a first electrode ELT1 of a corresponding pixel PXL through a contact hole (e.g., a first contact hole CH1 and/or a bridge pattern BRP) penetrating through the passivation layer PSV.

In an embodiment, at least one signal line and/or at least one power line, electrically connected to each pixel PXL, and an electrode of the circuit elements constituting the pixel circuit PXC may be disposed in the same layer. In an example, the scan line Si of each pixel PXL and the gate electrodes GE of the transistors T may be disposed in the same layer. The data line Dj of each pixel PXL and the first and second transistor electrodes TE1 and TE2 of the transistors T may be disposed in (or on) the same layer.

The first power line PL1 and/or the second power line PL2 and the gate electrodes GE or the first and second transistor electrodes TE1 and TE2 of the transistors T may be disposed in (or on) the same layer or in different layers. In an example, the second power line PL2 for supplying the second power source VSS may be disposed on the second interlayer insulating layer ILD2 to be at least partially covered or overlapped by the passivation layer PSV. The second power line PL2 may be electrically connected to a second electrode ELT2 of a light source unit LSU disposed on the passivation layer PSV through a second contact hole CH2 penetrating through the passivation layer PSV. However, the position and/or structure of the first power line PL1 and/or the second power line PL2 may be variously changed. For example, the second power line PL2 may be disposed in the same layer as the gate electrodes GE or the first and second transistor electrodes TE1 and TE2 of the transistors T to be electrically connected to the second electrode ELT2 through at least one bridge pattern (not illustrated) and/or the second contact hole CH2.

The second interlayer insulating layer ILD2 may be disposed on the first interlayer insulating layer ILD1 and may cover or overlap the first and second transistor electrodes TE1 and TE2 located on the first interlayer insulating layer ILD1. The second interlayer insulating layer ILD2 may be formed as a single layer or a multi-layer and may include at least one inorganic material and/or at least one organic material. For example, the second interlayer insulating layer ILD2 may include various kinds of organic/inorganic insulating materials including silicon nitride (SiNₓ), silicon oxide (SiOₓ), silicon oxynitride (SiOₓN_{y}), or the like, but the disclosure is not limited thereto.

The bridge pattern BRP for connecting at least one circuit element (e.g., the first transistor T1) provided in the pixel circuit PXC to the first electrode ELT1, the first power line PL1, and/or the second power line PL2 may be disposed on the second interlayer insulating layer ILD2. However, in some embodiments, the second interlayer insulating layer ILD2 may be omitted. The bridge pattern BRP, etc. illustrated in FIG. 8 may be omitted, and the second power line PL2 may be disposed in a layer in which an electrode of the transistor T is disposed.

The passivation layer PSV may be disposed over the circuit elements including the transistors T and/or the lines including the first and second power lines PL1 and PL2. The passivation layer PSV may be formed as a single layer or a multi-layer and may include at least one inorganic insulating material and/or at least one organic insulating material. In an example, the passivation layer PSV may include at least one organic insulating layer and may function to substantially planarize a surface of the circuit layer PCL.

The display layer DPL may be disposed on the passivation layer PSV of the circuit layer PCL. The display layer DPL may include a first bank BNK1 located at a boundary of each pixel PXL, at least one pair of first and second electrodes ELT1 and ELT2 disposed in a light emission area EMA of each pixel PXL to form each light source unit LSU, and at least one light emitting element LD electrically connected between the first electrode ELT1 and the second electrode ELT2. A light emitting element LD disposed in each pixel PXL has been illustrated in FIGS. 7 and 8. However, similar to the embodiments illustrated in FIG. 4 and the like, each pixel PXL may include light emitting elements LD electrically connected between the first and second electrodes ELT1 and ELT2. Therefore, each embodiment will hereinafter be described assuming that the pixel PXL includes light emitting elements LD.

The display layer DPL may further include first and second contact electrodes CNE1 and CNE2 for more stably connecting the light emitting elements LD between the first and second electrodes ELT1 and ELT2, and a second bank BNK2 for allowing an area of each of the first and second electrodes ELT1 and ELT2 and/or the first and second contact electrodes CNE1 and CNE2 to protrude upward.

The second bank BNK2 may be disposed on the circuit layer PCL. The second bank BNK2 may be formed as a separated or integrated pattern. The second bank BNK2 may protrude in a height direction of the substrate SUB, for example, the third direction (Z-axis direction).

In some embodiments, the second bank BNK2 may have various shapes. In an embodiment, the second bank BNK2 may be a bank structure having a regular tapered structure. For example, as illustrated in FIGS. 7 and 8, the second bank BNK2 may be formed to have an inclined surface inclined at a predetermined angle with respect to the substrate SUB. However, the disclosure is not necessarily limited thereto, and the second bank BNK2 may have a sidewall having a curved shape, a stepped shape, or the like. In an example, the second bank BNK2 may have a section having a semicircular shape, a semi-elliptical shape, or the like.

Electrodes and insulating layers, which are disposed on the top of the second bank BNK2, may have a shape, at least a portion of which corresponds to the second bank BNK2. In an example, the first and second electrodes ELT1 and ELT2 and the first and second contact electrodes CNE1 and CNE2 may be disposed on an area of the second bank BNK2 and may include an inclined surface or a curved surface, which has a shape corresponding to that of the second bank BNK2. Similarly, a first insulating layer INS1, a third insulating layer INS3, and/or a fourth insulating layer INS4 may be disposed over the second bank BNK2 and may include an inclined surface or a curved surface, which has a shape corresponding to that of the second bank BNK2.

The second bank BNK2 may include an insulating material including at least one inorganic material and/or at least one organic material. In an example, the second bank BNK2 may include at least one inorganic layer including various inorganic insulating materials including silicon nitride (SiNₓ), silicon oxide (SiOₓ), etc. As another example, the second bank BNK2 may include at least one organic layer and/or at least one photoresist layer including various organic insulating materials or may be formed as a single layer insulator or multi-layered insulator including organic/inorganic materials. The material and/or pattern shape of the second bank BNK2 may be variously modified.

In an embodiment, the second bank BNK2 may function as a reflective member. In an example, the second bank BNK2 along with the first and second electrodes ELT1 and ELT2 provided on the second bank BNK2 may function as a reflective member for guiding light emitted from each light emitting element LD in a desired direction (e.g., an upward direction of the pixel PXL), thereby improving the light efficiency of the pixel PXL.

Each of the first and second electrodes ELT1 and ELT2 forming pixel electrodes of each pixel PXL may be disposed on the second bank BNK2. Each of the first and second electrodes ELT1 and ELT2 may be directly on the second bank BNK2 to overlap the second bank BNK2. The first electrode ELT1 and the second electrode ELT2 may be disposed in a pixel area provided and/or formed by each pixel PXL. For example, the first electrode ELT1 and the second electrode ELT2 may be disposed in the light emission area EMA of each pixel PXL. The first electrode ELT1 and the second electrode ELT2 may be disposed to be spaced apart from each other. In an example, the first and second electrodes ELT1 and ELT2 may be disposed side by side to be spaced apart from each other at a predetermined distance in each light emission area EMA.

In some embodiments, the first electrode ELT1 and/or the second electrode ELT2 may have a pattern(s) separated for each pixel PXL or have a pattern(s) commonly connected in pixels PXL. In a process of forming pixels PXL, particularly, before alignment of light emitting elements LD are completed, first electrodes ELT1 of the pixels PXL disposed in the display area DA may be electrically connected to each other, and second electrodes ELT2 of the pixels PXL may be electrically connected to each other. For example, before the alignment of the light emitting elements LD is completed, the first electrodes ELT1 of the pixels PXL may be integrally or non-integrally formed and may be electrically connected to each other, and the second electrodes ELT2 of the pixels PXL may be integrally or non-integrally formed and may be electrically connected to each other. In case that the first electrodes ELT1 or the second electrodes ELT2 of the pixels PXL are non-integrally connected to each other, the first electrodes ELT1 or the second electrodes ELT2 may be electrically connected to each other by at least one contact hole and/or at least one bridge pattern.

The first and second electrodes ELT1 and ELT2 may be respectively supplied with a first alignment signal (or first alignment voltage) and a second alignment signal (or second alignment voltage) when the light emitting elements LD are aligned. In an example, one of the first and second electrodes ELT1 and ELT2 may be supplied with an alignment signal in an AC form, and the other of the first and second electrodes ELT1 and ELT2 may be supplied with an alignment voltage (e.g., a ground voltage) having a constant voltage level. For example, a predetermined alignment signal may be applied to the first and second electrodes ELT1 and ELT2 when the light emitting elements LD are aligned. Accordingly, an electric field may be formed between the first and second electrodes ELT1 and ELT2. The light emitting elements LD supplied to each pixel area (particularly, the light emission area EMA of each pixel PXL) may be self-aligned between the first and second electrodes ELT1 and ELT2 by the electric field. After the alignment of the light emitting elements LD is completed, the connection between at least the first electrodes ELT1 may be electrically disconnected between the pixels PXL, so that the pixels PXL may be individually driven.

The first electrode ELT1 may be electrically connected to a predetermined circuit element (e.g., at least one transistor constituting the pixel circuit PXC), a predetermined power line (e.g., the first power line PL1), and/or a predetermined signal line (e.g., the scan line Si, the data line Dj, or a predetermined control line) through the first contact hole CH1. In an embodiment, the first electrode ELT1 may be electrically connected to the bridge pattern BRP through the first contact hole CH1 and may thus be electrically connected to the transistor T. However, the disclosure is not necessarily limited thereto, and the first electrode ELT may be directly electrically connected to the predetermined power line or the predetermined signal line.

The second electrode ELT2 may be electrically connected to a predetermined circuit element (e.g., at least one transistor constituting the pixel circuit PXC), a predetermined power line (e.g., the second power line PL2), and/or a predetermined signal line (e.g., the scan line Si, the data line Dj, or a predetermined control line) through the second contact hole CH2. In an embodiment, the second electrode ELT2 may be electrically connected to the second power line PL2 through the second contact hole CH2. However, the disclosure is not necessarily limited thereto, and the second electrode ELT2 may be directly electrically connected to the predetermined power line or the predetermined signal line.

Each of the first and second electrodes ELT1 and ELT2 may include at least one conductive material. In an example, each of the first and second electrodes ELT1 and ELT2 may include at least one metal of various metallic materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and the like, or an alloy including the at least one metal, at least one conductive oxide such as indium tin oxide (ITO), indium zinc oxide (IZO), indium tin zinc oxide (ITZO), zinc oxide (ZnO), aluminum doped zinc oxide (AZO), gallium doped zinc oxide (GZO), zinc tin oxide (ZTO), gallium tin oxide (GTO), and fluorine doped tin oxide (FTO), and at least one conductive material among conductive polymers such as PEDOT, but the disclosure is not limited thereto. For example, each of the first and second electrodes ELT1 and ELT2 may include other conductive materials including carbon nanotubes, graphene, etc. Each of the first and second electrodes ELT1 and ELT2 may be formed as a single layer or multiple layers. In an example, each of the first and second electrodes ELT1 and ELT2 may include a reflective electrode layer including a reflective conductive material. Each of the first and second electrodes ELT1 and ELT2 may selectively further include at least one of at least one transparent electrode layer disposed on the top and/or bottom of the reflective electrode layer and at least one conductive capping layer covering or overlapping the top of the reflective electrode layer and/or the transparent electrode layer.

The first bank BNK1 and the first insulating layer INS1 may be disposed on the first and second electrodes ELT1 and ELT2. The first bank BNK1 and the first insulating layer INS1 may be simultaneously formed by the same process to be disposed in (or on) the same layer. The first bank BNK1 and the first insulating layer INS1 may be made of the same material. In an embodiment, the first bank BNK1 and the first insulating layer INS1 may include a chemically amplified resist (CAR). The CAR may include a photoacid generator (PAG). The PAG may include at least one of triphenylsulfonium triflate, triphenylsulfonium nonaflate, triphenylsulfonium perfluorooctylsulfonate, triarylsulfonium triflate, triarylsulfonium nonaflate, triarylsulfonium perfluorooctylsulfonate, a triphenylsulfonium salt, a triarylsulfonium salt, a triarylsulfonium hexafluoroantimonate salt, N-hydroxynaphthalimide triflate, 1,1-bis[p-chlorophenyl]-2,2,2-trichloroethane (DDT), 1,1-bis[p-methoxyphenyl]-2,2,2-trichloroethane, 1,2,5,6,9,10-hexabromocyclododecane, 1,10-dibromodecane, 1,1-bis[p-chlorophenyl]2,2-dichloroethane, 4,4-dichloro-2-(trichloromethyl)benzhydrol, 1,1-bis(chlorophenyl) 2-2,2-trichloroethanol, hexachlorodimethylsulfone, 2-chloro-6-(trichloromethyl)pyridine, or derivatives thereof, but the disclosure is not necessarily limited thereto.

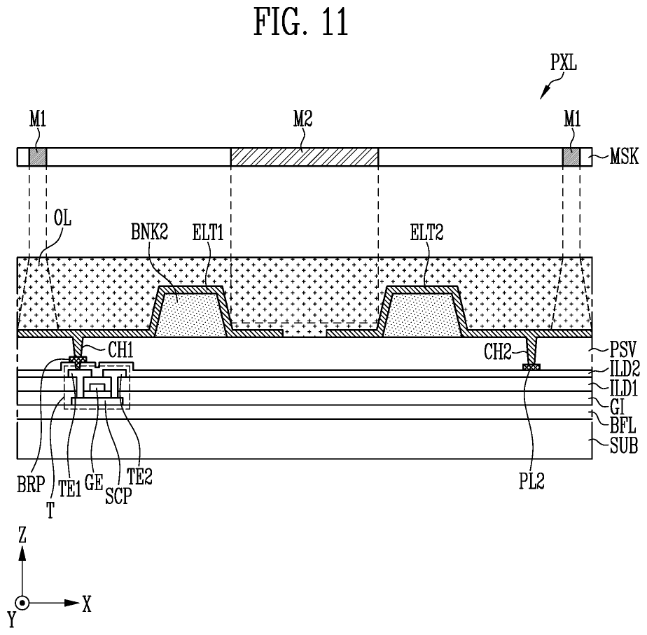

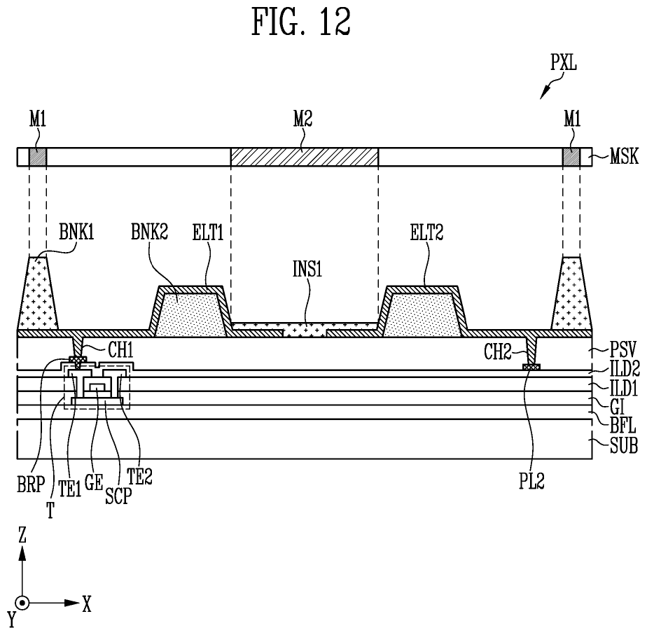

As described above, in case that the first bank BNK1 and the first insulating layer INS1 are formed by using the CAR, i.e., a high-resolution and high-sensitivity material, the height and taper angle of the first bank BNK1 may increase and a fine pattern of the first insulating layer INS1 may be readily implemented. In case that the first bank BNK1 and the first insulating layer INS1 are simultaneously formed by the same process, manufacturing cost may be reduced by decreasing the number of masks, and a manufacturing process may be simplified. This will be described in detail below with reference to FIGS. 11 and 12.

The first bank BNK1 may surround the light emission area EMA of each pixel PXL. For example, the first bank BNK1 may be disposed in a boundary area of each pixel area in which a pixel PXL is provided and/or an area between adjacent pixels PXL. The first bank BNK1 may include an opening defining the light emission area EMA of each pixel PXL. Each light emission area EMA may be partitioned by the first bank BNK1, and thus light emitting elements LD described below may be supplied to each light emission area EMA. For example, in case that light emitting elements LD are supplied to each light emission area EMA, the first bank BNK1 may function as a dam structure defining each light emission area EMA to which the light emitting elements LD are to be supplied.

The first insulating layer INS1 may be formed to partially cover or overlap first areas of the first and second electrodes ELT1 and ELT2 and may expose other areas of the first and second electrodes ELT1 and ELT2. The first and second contact electrodes CNE1 and CNE2 described below may be electrically connected to the first and second electrodes ELT1 and ELT2 exposed by the first insulating layer INS1.

Light emitting elements LD may be supplied and aligned on the first and second electrodes ELT1 and ELT2 and the first insulating layer INS1. The light emitting elements LD may be aligned between the first and second electrodes ELT1 and ELT2 on the first insulating layer INS1. In an example, light emitting elements LD may be supplied to the light emission area EMA of each pixel by an inkjet process, a slit coating process, or other various processes. The light emitting elements LD may be aligned to have a directionality between the first and second electrodes ELT1 and ELT2 by a predetermined alignment signal (or alignment voltage) applied to each of the first and second electrodes ELT1 and ELT2.

In an embodiment, at least some of the light emitting elements LD may be disposed between a pair of adjacent first and second electrodes ELT1 and ELT2 such that both end portions (i.e., first and second end portions EP1 and EP2) thereof overlap the pair of adjacent first and second electrodes ELT1 and ELT2. In another embodiment, at least some of the light emitting elements LD may be disposed between a pair of adjacent first and second electrodes ELT1 and ELT2 not to overlap the first electrode ELT1 and/or the second electrode ELT2, and each of the light emitting elements LD may be electrically connected to the pair of first and second electrodes ELT1 and ELT2 through the first and second contact electrodes CNE1 and CNE2. Each of the light emitting elements LD electrically connected between the first and second electrodes ELT1 and ELT2 may form an effective light source of a corresponding pixel PXL. The effective light sources may form a light source unit LSU of the corresponding pixel PXL.

The second insulating layer INS2 may be disposed on first areas of the light emitting elements LD. For example, the second insulating layer INS2 may be disposed on one area of each of the light emitting elements LD to expose first and second end portions EP1 and EP2 of each of the light emitting elements LD. In an example, the second insulating layer INS2 may be locally disposed only on one area of each of the light emitting elements LD including a central area of each of the light emitting elements LD. In case that the second insulating layer INS2 is formed on the light emitting elements LD after the light emitting elements LD are completely aligned, the light emitting elements LD may be prevented from being displaced from positions at which the light emitting elements LD are aligned.

The second insulating layer INS2 may be formed as an independent pattern in the light emission area EMA of each pixel PXL, but the disclosure is not limited thereto. In some embodiments, the second insulating layer INS2 may be omitted, and an end of each of the first and second contact electrodes CNE1 and CNE2 may be directly located on each of the light emitting elements LD.

The second insulating layer INS2 may be formed as a single layer or a multi-layer and may include at least one inorganic insulating material and/or at least one organic insulating layer. For example, the second insulating layer INS2 may include various organic/inorganic insulating materials including silicon nitride (SiNₓ), silicon oxide (SiOₓ), aluminum oxide (AlₓO_{y}), a photoresist (PR) material, or the like.

Both end portions, for example, the first and second end portions EP1 and EP2 which are not overlapped by the second insulating layer INS2 may be respectively overlapped by the first and second contact electrodes CNE1 and CNE2. The first and second contact electrodes CNE1 and CNE2 may be formed to be spaced apart from each other. For example, adjacent first and second contact electrodes CNE1 and CNE2 may be disposed on the first and second end portions EP1 and EP2 of at least one adjacent light emitting element LD to be spaced apart from each other with the second insulating layer INS2 interposed therebetween.

The first and second contact electrodes CNE1 and CNE2 may be disposed on the top of the first and second electrodes ELT1 and ELT2 to overlap an exposed area of each of the first and second electrodes ELT1 and ELT2. For example, the first and second contact electrodes CNE1 and CNE2 may be disposed on at least one area of each of the first and second electrodes ELT1 and ELT2 to directly or indirectly contact the first and second electrodes ELT1 and ELT2 at an upper portion of the second bank BNK2 or at the periphery of the second bank BNK2. Accordingly, the first and second contact electrodes CNE1 and CNE2 may be electrically connected respectively to the first and second electrodes ELT1 and ELT2. The first and second electrodes ELT1 and ELT2 may be electrically connected to the first or second end portion EP1 or EP2 of at least one light emitting element LD through the first and second contact electrodes CNE1 and CNE2, respectively.

In an embodiment, the first and second contact electrodes CNE1 and CNE2 may be sequentially formed on different layers on the substrate SUB as illustrated in FIG. 7. The third insulating layer INS3 may be disposed between the first contact electrode CNE1 and the second contact electrode CNE2. An order in which the first and second contact electrodes CNE1 and CNE2 are formed may be changed in some embodiments. For example, in another embodiment, the second contact electrode CNE2 may be first formed before the first contact electrode CNE1 is formed, and the first contact electrode CNE1 may be formed on the third insulating layer INS3 after the third insulating layer INS3 is formed to overlap the second contact electrode CNE2 and the second insulating layer INS2. However, the disclosure is not necessarily limited thereto, and the first and second contact electrodes CNE1 and CNE2 may be disposed on the same layer as illustrated in FIG. 8. For example, the first and second contact electrodes CNE1 and CNE2 may be formed as the same conductive layer on the surface of the substrate SUB. The first and second contact electrodes CNE1 and CNE2 may be simultaneously formed by the same process, so that the manufacturing process of the pixel PXL and the display device having the same may be simplified. However, the disclosure is not necessarily limited thereto, and the first and second contact electrodes CNE1 and CNE2 may be sequentially formed.

The first and second contact electrodes CNE1 and CNE2 may be made of (or include) various transparent conductive materials. In an example, the first and second contact electrodes CNE1 and CNE2 may include at least one of various transparent conductive materials including indium tin oxide (ITO), indium zinc oxide (IZO), indium tin zinc oxide (ITZO), zinc oxide (ZnO), aluminum doped zinc oxide (AZO), gallium doped zinc oxide (GZO), zinc tin oxide (ZTO), gallium tin oxide (GTO), and fluorine doped tin oxide (FTO) and may be substantially transparent or translucent to satisfy a predetermined transmittance. Accordingly, light emitted from the light emitting elements LD through each of the first and second end portions EP1 and EP2 may be emitted to the outside of the display panel PNL while being transmitted through each of the first and second contact electrodes CNE1 and CNE2.

The third insulating layer INS3 may be disposed between the first contact electrode CNE1 and the second contact electrode CNE2. In case that the third insulating layer INS3 is formed between the first contact electrode CNE1 and the second contact electrode CNE2, the electrical stability between the first and second end portions EP1 and EP2 of the light emitting elements LD may be ensured. For example, the first and second contact electrodes CNE1 and CNE2 may be stably separated from each other by the third insulating layer INS3. Accordingly, a short-circuit defect may be effectively prevented from occurring between the first and second end portions EP1 and EP2 of the light emitting elements LD.

The third insulating layer INS3 may be formed as a single layer or a multi-layer and may include at least one inorganic insulating material and/or at least one organic insulating material. For example, the third insulating layer INS3 may include various organic/inorganic insulating materials including silicon nitride (SiNₓ), silicon oxide (SiOₓ), aluminum oxide (AlₓO_{y}), a photoresist (PR) material, or the like.

The fourth insulating layer INS4 may be disposed on the first and second contact electrodes CNE1 and CNE2 and/or the third insulating layer INS3. For example, the fourth insulating layer INS4 may overlap the second bank BNK2, the first and second electrodes ELT1 and ELT2, the first insulating layer INS1, the second insulating layer INS2, and/or the third insulating layer INS3, the light emitting elements LD, and the first and second contact electrodes CNE1 and CNE2. The fourth insulating layer INS4 may include at least one inorganic layer and/or at least one organic insulating layer.

The fourth insulating layer INS4 may be formed as a single layer or a multi-layer and may include at least one inorganic insulating material and/or at least one organic insulating material. For example, the fourth insulating layer INS4 may include various organic/inorganic insulating materials including silicon nitride (SiNₓ), silicon oxide (SiOₓ), aluminum oxide (AlₓO_{y}), a photoresist (PR) material, or the like.

In an embodiment, the fourth insulating layer INS4 may include a thin film encapsulation layer having a multi-layered structure. For example, the fourth insulating layer INS4 may be formed as a thin film encapsulation layer having a multi-layered structure including at least two organic insulating layers and at least one organic insulating layer interposed between the at least two inorganic insulating layers. However, the disclosure is not necessarily limited thereto, and the material and/or structure of the fourth insulating layer INS4 may be variously modified.

The display device in accordance with the above-described embodiment may include the first bank BNK1 and the first insulating layer INS1, which are simultaneously formed by using the CAR, i.e., a high-resolution and high-sensitivity material. Accordingly, the height and taper angle of the first bank BNK1 may increase, and the fine pattern of the first insulating layer INS1 may be readily implemented. The manufacturing cost may be reduced by decreasing the number of masks, and the manufacturing process may be simplified.

Hereinafter, another embodiment will be described. In the following embodiment, components identical to those which have already been described are designated by like reference numerals, and repetitive descriptions thereof will be omitted or simplified.

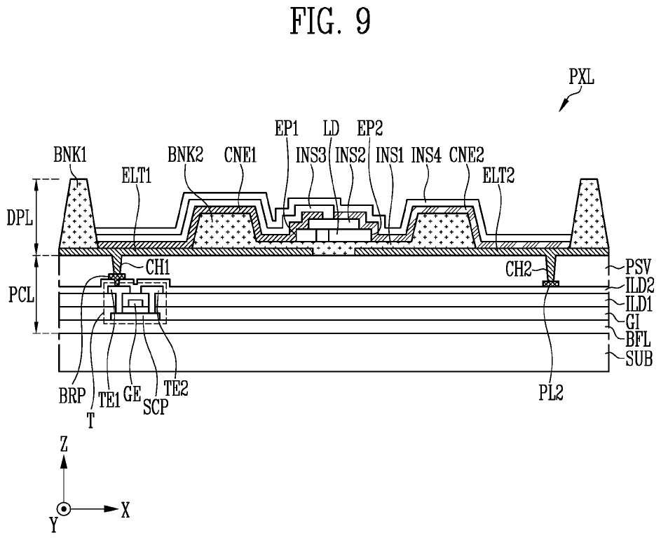

FIG. 9 is a schematic cross-sectional view illustrating a pixel of a display device in accordance with an embodiment.

Referring to FIG. 9, the display device in accordance with this embodiment may be different from the embodiment illustrated in FIGS. 1 to 8 at least in that the second bank BNK2 is disposed on the top of the first and second electrodes ELT1 and ELT2.

Specifically, the second bank BNK2 may be disposed between the first and second electrodes ELT1 and ELT2 and the first and second contact electrodes CNE1 and CNE2. The second bank BNK2, the first bank BNK1, and the first insulating layer INS1 may be simultaneously formed by the same process and may be disposed on the same layer. The second bank BNK2, the first bank BNK1, and the first insulating layer INS1 may be made of the same material. In an embodiment, the second bank BNK2 may include a chemically amplified resist (CAR). The CAR may include a photoacid generator (PAG). The PAG may include at least one of triphenylsulfonium triflate, triphenylsulfonium nonaflate, triphenylsulfonium perfluorooctylsulfonate, triarylsulfonium triflate, triarylsulfonium nonaflate, triarylsulfonium perfluorooctylsulfonate, a triphenylsulfonium salt, a triarylsulfonium salt, a triarylsulfonium hexafluoroantimonate salt, N-hydroxynaphthalimide triflate, 1,1-bis[p-chlorophenyl]-2,2,2-trichloroethane (DDT), 1,1-bis[p-methoxyphenyl]-2,2,2-trichloroethane, 1,2,5,6,9,10-hexabromocyclododecane, 1,10-dibromodecane, 1,1-bis[p-chlorophenyl]2,2-dichloroethane, 4,4-dichloro-2-(trichloromethyl)benzhydrol, 1,1-bis(chlorophenyl) 2-2,2-trichloroethanol, hexachlorodimethylsulfone, 2-chloro-6-(trichloromethyl)pyridine, or derivatives thereof, but the disclosure is not necessarily limited thereto.

The display device in accordance with the embodiment may include the first bank BNK1, the second bank BNK2, and the insulating layer INS, which are simultaneously formed by using the CAR, for example, a high-resolution and high-sensitivity material. Accordingly, the manufacturing cost may be reduced by decreasing the number of masks, and the manufacturing process may be simplified, as described above.

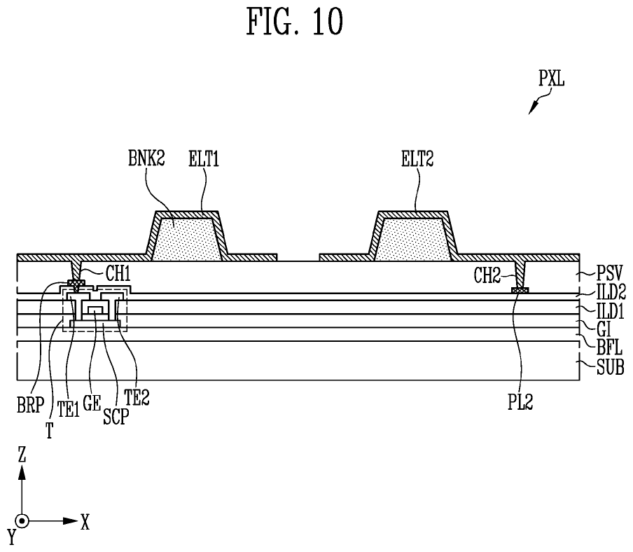

FIGS. 10 to 14 are schematic cross-sectional views illustrating a method of manufacturing a display device in accordance with an embodiment. FIGS. 10 to 14 are schematic cross-sectional views illustrating a method of manufacturing the display device illustrated in FIG. 7. In FIGS. 10 to 14, components substantially identical to those illustrated in FIG. 7 are denoted by like reference numerals, and detailed descriptions thereof will be omitted.

Referring to FIG. 10, a substrate SUB, on which the above-described transistor T and the like are formed, may be first prepared, and a second bank BNK2 and first and second electrodes ELT1 and ELT2 may be formed on the substrate SUB on which a plurality of pixels PXL are defined. The second bank BNK2 may be first formed on the substrate SUB, and the first and second electrodes ELT1 and ELT2 may be formed on the second bank BNK2. However, an order in which the second bank BNK2 and the first and second electrode ELT1 and ELT2 are formed is not necessarily limited thereto and may be changed in some embodiments.

Referring to FIG. 11, subsequently, an organic layer OL may be formed on the substrate SUB on which the second bank BNK2 and the first and second electrodes ELT1 and ELT2 are formed. The organic layer OL may include a chemically amplified resist (CAR). The CAR may include a photoacid generator (PAG). The PAG may include at least one of triphenylsulfonium triflate, triphenylsulfonium nonaflate, triphenylsulfonium perfluorooctylsulfonate, triarylsulfonium triflate, triarylsulfonium nonaflate, triarylsulfonium perfluorooctylsulfonate, a triphenylsulfonium salt, a triarylsulfonium salt, a triarylsulfonium hexafluoroantimonate salt, N-hydroxynaphthalimide triflate, 1,1-bis[p-chlorophenyl]-2,2,2-trichloroethane (DDT), 1,1-bis[p-methoxyphenyl]-2,2,2-trichloroethane, 1,2,5,6,9,10-hexabromocyclododecane, 1,10-dibromodecane, 1,1-bis[p-chlorophenyl]2,2-dichloroethane, 4,4-dichloro-2-(trichloromethyl)benzhydrol, 1,1-bis(chlorophenyl) 2-2,2-trichloroethanol, hexachlorodimethylsulfone, 2-chloro-6-(trichloromethyl)pyridine, or derivatives thereof, but the disclosure is not necessarily limited thereto.

Referring to FIG. 12, subsequently, a first bank BNK1 and a first insulating layer INS1 may be formed by patterning the organic layer OL. In case that the first bank BNK1 and the first insulating layer INS1 are formed by using the organic layer including the CAR, i.e., a high-resolution and high-sensitivity material, the height and taper angle of the first bank BNK1 may increase, and a fine pattern of the first insulating layer INS1 may be readily implemented. In case that the first bank BNK1 and the first insulating layer INS1 are simultaneously formed by the same process, manufacturing may be reduced by decreasing the number of masks, and a manufacturing process may be simplified. The first bank BNK1 and the first insulating layer INS1 may be simultaneously formed by the same process. Accordingly, the number of masks may be decreased, and the manufacturing process may be simplified, as described above. In an embodiment, the first bank BNK1 and the first insulating layer INS1 may be simultaneously formed by using a halftone mask. For example, a mask MSK may include a first mask area M1 corresponding to the first bank BNK1 and a second mask area M2 corresponding to the first insulating layer INS1. A transmittance of the first mask area M1 may be different from that of the second mask area M2. For example, in case that the organic layer OL is a positive photosensitive organic layer, the transmittance of the first mask area M1 may be smaller than that of the second mask area M2, but the disclosure is not necessarily limited thereto.

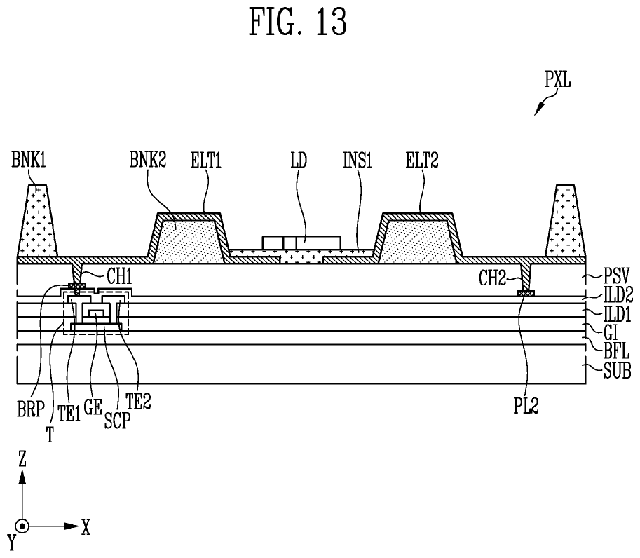

Referring to FIG. 13, subsequently, light emitting elements LD may be provided between the first and second electrodes ELT1 and ELT2 on the first insulating layer INS1. The light emitting elements LD may be prepared in a form in which the light emitting elements LD are dispersed in a predetermined solution and may be supplied to a light emission area EMA of each of the pixels PXL by an inkjet printing process, a slit coating process, or the like. In an example, the light emitting elements LD may be supplied to each light emission area EMA while being mixed with a volatile solvent. In case that a predetermined voltage is supplied through the first and second electrodes ELT1 and ELT2 of each of the pixels PXL, the light emitting elements LD may be aligned between the first and second electrodes ELT1 and ELT2 while an electric field is formed between the first and second electrodes ELT1 and ELT2. After the light emitting elements LD are aligned, the solvent may be volatilized or removed in another manner, so that the light emitting elements LD may be stably arranged between the first and second electrodes ELT1 and ELT2.

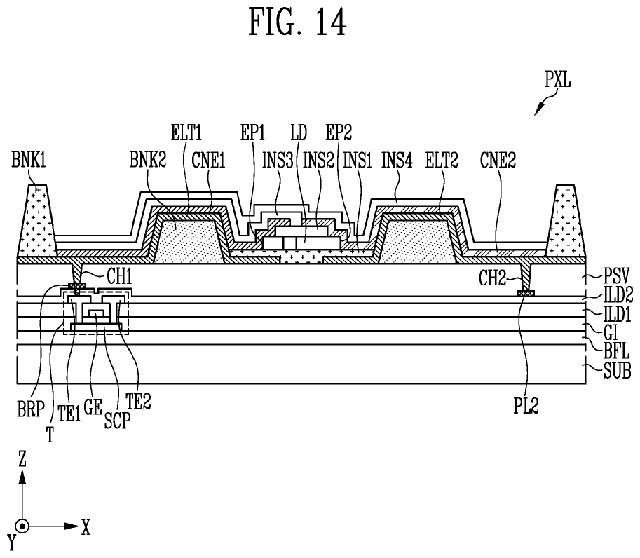

Referring to FIG. 14, subsequently, a second insulating layer INS2, first and second contact electrodes CNE1 and CNE2, a third insulating layer INS3, and a fourth insulating layer INS4 may be formed on the light emitting elements LD, and the display device illustrated in FIG. 7 may be completed.

Hereinafter, another embodiment will be described. In the following embodiment, components identical to those which have already been described are designated by like reference numerals, and repetitive descriptions thereof will be omitted or simplified.

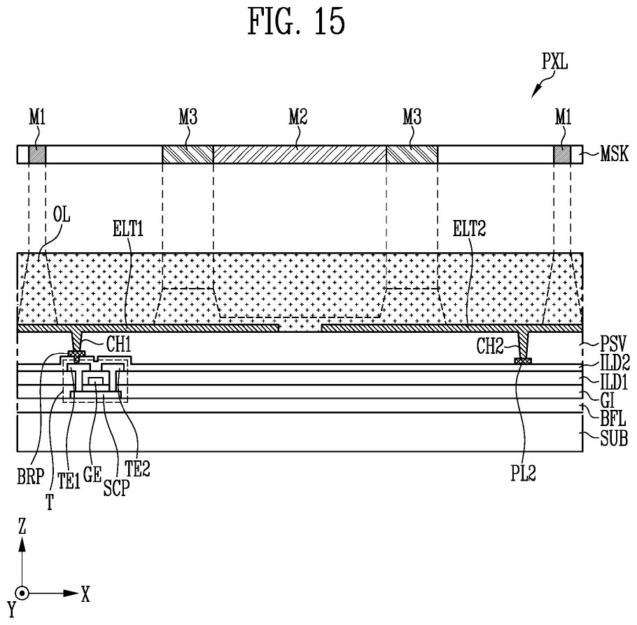

FIGS. 15 to 18 are schematic cross-sectional views illustrating a method of manufacturing a display device in accordance with an embodiment. FIGS. 15 to 18 are schematic sectional views illustrating a method of manufacturing the display device illustrated in FIG. 9. In FIGS. 15 to 18, components substantially identical to those illustrated in FIG. 9 are designated by like reference numerals, and detailed descriptions thereof will be omitted.

Referring to FIG. 15, an organic layer OL may be first formed on a substrate SUB on which first and second electrodes ELT1 and ELT2 are formed. The organic layer OL may include a chemically amplified resist (CAR). The CAR may include a photoacid generator (PAG). The PAG may include at least one of triphenylsulfonium triflate, triphenylsulfonium nonaflate, triphenylsulfonium perfluorooctylsulfonate, triarylsulfonium triflate, triarylsulfonium nonaflate, triarylsulfonium perfluorooctylsulfonate, a triphenylsulfonium salt, a triarylsulfonium salt, a triarylsulfonium hexafluoroantimonate salt, N-hydroxynaphthalimide triflate, 1,1-bis[p-chlorophenyl]-2,2,2-trichloroethane (DDT), 1,1-bis[p-methoxyphenyl]-2,2,2-trichloroethane, 1,2,5,6,9,10-hexabromocyclododecane, 1,10-dibromodecane, 1,1-bis[p-chlorophenyl]2,2-dichloroethane, 4,4-dichloro-2-(trichloromethyl)benzhydrol, 1,1-bis(chlorophenyl) 2-2,2-trichloroethanol, hexachlorodimethylsulfone, 2-chloro-6-(trichloromethyl)pyridine, or derivatives thereof, but the disclosure is not necessarily limited thereto.

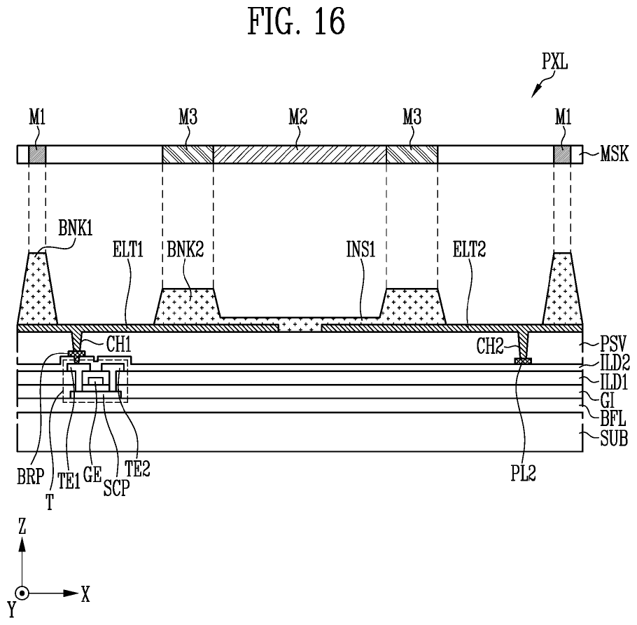

Referring to FIG. 16, subsequently, a first bank BNK1, a second bank BNK2, and a first insulating layer INS1 may be formed by patterning the organic layer OL. In case that the first bank BNK1 and the first insulating layer INS1 are formed by using the organic layer including the CAR, for example, a high-resolution and high-sensitivity material, the height and taper angle of the first bank BNK1 may increase, and a fine pattern of the first insulating layer INS1 may be readily implemented. In case that the first bank BNK1 and the first insulating layer INS1 are simultaneously formed by the same process, manufacturing cost may be reduced by decreasing the number of masks, and a manufacturing process may be simplified. The first bank BNK1, the second bank BNK2, and the first insulating layer INS1 may be simultaneously formed by the same process by patterning the organic layer OL. Accordingly, the number of masks may be decreased, and the manufacturing process may be simplified, as described above. In an embodiment, the first bank BNK1, the second bank BNK2, and the first insulating layer INS1 may be simultaneously formed by using a halftone mask. For example, a mask MSK may include a first mask area M1 corresponding to the first bank BNK1, a second mask area M2 corresponding to the first insulating layer INS1, and a third mask area M3 corresponding to the second bank BNK2. Transmittances of the first to third mask areas M1, M2, and M3 may be different from one another. For example, in case that the organic layer OL is a positive photosensitive organic layer, the transmittance of the first mask area M1 may be smaller than those of the second mask area M2 and the third mask area M3. The transmittance of the third mask area M3 may be smaller than that of the second mask area M2, but the disclosure is not necessarily limited thereto.

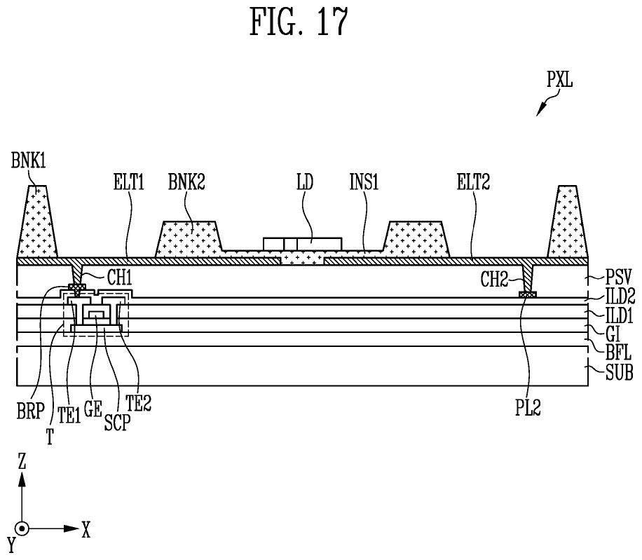

Referring to FIG. 17, subsequently, light emitting elements LD may be provided between the first and second electrodes ELT1 and ELT2 on the first insulating layer INS1. A process of supplying and aligning the light emitting elements LD has been described with reference to FIG. 13, and therefore, repetitive descriptions thereof will be omitted.

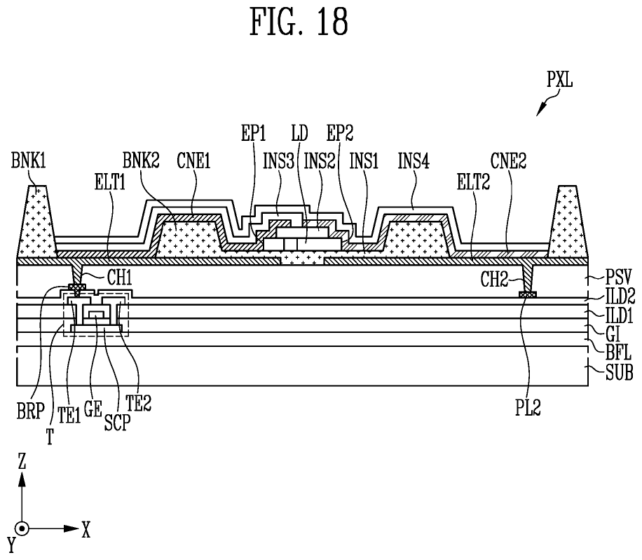

Referring to FIG. 18, subsequently, a second insulating layer INS2, first and second contact electrodes CNE1 and CNE2, a third insulating layer INS3, and a fourth insulating layer INS4 may be formed on the light emitting elements LD, and the display device illustrated in FIG. 9 may be completed.

In accordance with the disclosure, a first bank and a first insulating layer may be simultaneously formed by using a chemically amplified resist (CAR), for example, a high-resolution and high-sensitivity material. Therefore, the height and taper angle of the first bank may increase, and a fine pattern of the first insulating layer may be readily implemented. Manufacturing cost may be reduced by decreasing the number of masks, and a manufacturing process may be simplified.

Some embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Therefore, it will be understood by those of skill in the art that various changes in form and details may be made without departing from the spirit and scope of the disclosure.

What is claimed is:

1. A display device comprising:
a substrate including a plurality of pixels;
a first bank disposed at a boundary of the plurality of pixels;
a first electrode and a second electrode spaced apart from each other on the substrate;
an insulating layer disposed on the first electrode and the second electrode; and
a plurality of light emitting elements disposed between the first electrode and the second electrode on the insulating layer,
wherein the first bank and the insulating layer are disposed on a same layer.

2. The display device of claim 1, wherein the first bank and the insulating layer include a same material.

3. The display device of claim 2, wherein the first bank and the insulating layer include a chemically amplified resist (CAR).

4. The display device of claim 1, further comprising a second bank disposed between the first and second electrodes and the substrate.

5. The display device of claim 4, wherein the first electrode and the second electrode directly overlap the second bank.

6. The display device of claim 1, further comprising a second bank disposed on the first electrode and the second electrode.

7. The display device of claim 6, wherein the second bank, the first bank, and the insulating layer are disposed on a same layer.

8. The display device of claim 6, wherein the second bank, the first bank, and the insulating layer include a same material.

9. The display device of claim 6, wherein the second bank includes a chemically amplified resist (CAR).

10. The display device of claim 1, further comprising:
a first contact electrode electrically connecting an end of the light emitting element and the first electrode; and
a second contact electrode electrically connecting another end of the light emitting element and the second electrode.

11. A method of manufacturing a display device, comprising:
providing a first electrode and a second electrode on a substrate on which a plurality of pixels are formed;
providing a first bank at a boundary of the plurality of pixels;
providing an insulating layer on the first electrode and the second electrode; and
providing a plurality of light emitting elements between the first electrode and the second electrode on the insulating layer,
wherein the first bank and the insulating layer are simultaneously formed.

12. The method of claim 11, wherein the providing of the first bank and the insulating layer includes:
providing an organic layer on the substrate; and
simultaneously forming the first bank and the insulating layer by patterning the organic layer.

13. The method of claim 12, wherein the organic layer includes a chemically amplified resist (CAR).

14. The method of claim 12, wherein
a mask is used in the patterning of the organic layer, the mask including a first mask area corresponding to the first bank and a second mask area corresponding to the insulating layer, and
a transmittance of the first mask area is different from a transmittance of the second mask area.

15. The method of claim 11, further comprising providing a second bank between the first and second electrodes and the substrate.

16. The method of claim 11, further comprising providing a second bank on the first electrode and the second electrode.

17. The method of claim 16, wherein the second bank, the first bank, and the insulating layer are simultaneously formed.

18. The method of claim 16, wherein the providing of the second bank includes:
providing an organic layer on the substrate; and
simultaneously forming the first bank, the second bank, and
the insulating layer by patterning the organic layer.

19. The method of claim 18, wherein the organic layer includes a chemically amplified resist (CAR).

20. The method of claim 11, further comprising providing:
a first contact electrode electrically connecting one end of the light emitting element and the first electrode; and
a second contact electrode electrically connecting another end of the light emitting element and the second electrode.
